(19) United States
(12) Patent Application Publication
(10) Pub. No.: US 2025/0357910 A1
(43) Pub. Date: Nov. 20, 2025

(54) RESONATOR AND METHOD FOR FORMING THE SAME

(71) Applicant: AAC Technologies Pte. Ltd., Singapore (SG)

(72) Inventors: ShirNee Yap, Singapore (SG); LiEng Loo, Singapore (SG); Kahkeen Lai, Singapore (SG); DongLiang Pang, Singapore (SG); Ke Wu, Shenzhen (CN)

(21) Appl. No.: 18/666,866

(22) Filed: May 17, 2024

(51) Int. Cl. H03H 9/13; H03H 3/02; H03H 9/05; H03H 9/17

(52) U.S. Cl. CPC H03H 9/131; H03H 3/02; H03H 9/0504; H03H 9/173

(57) ABSTRACT

A resonator and a method therefor. The resonator includes a substrate; a bottom electrode; a piezoelectric layer, a surface of the piezoelectric layer being provided with a recessed frame; a barrier layer, the barrier layer and the piezoelectric layer being partially spaced to form an air gap region; a shunt metal layer, along a thickness direction of the resonator, projection profiles of the recessed frame and the air gap region being both located within a projection profile of the shunt metal layer; and a top electrode, a protruding frame being provided at a surface of the top electrode, and a projection profile of the protruding frame being located at an edge of the resonance region. The resonator and the method therefor provide greater flexibility in frequency tuning while catering to the needs of different bandwidths; and also improve the quality factor Q value of the resonator.

### TECHNICAL FIELD

The present disclosure relates to the technical field of resonators, and in particular, to a resonator and a method for forming a resonator.

### BACKGROUND

With the increasing number of smart devices and the increasing popularity of IoT and 5G technologies, there is an increasing demand for high-performance filters and multiplexers. As an important part of filters and multiplexers, acoustic resonators have been the focus of research in recent years. The current mainstream acoustic resonance technologies include surface acoustic wave (SAW) technology and bulk acoustic wave (BAW) technology. Resonators using SAW technology take a mainstream market at mid-low frequencies (below 2 GHz) due to their simple manufacturing process and low cost. The disadvantages of SAW resonators include: a low quality factor value, a poor temperature drift of the material and poor compatibility with semiconductor processes. A filter formed by such a resonator has a poor rectangular coefficient, a high insertion loss, and a large center frequency drift with temperature. Moreover, as the frequency increases, a spacing between finger electrodes of the SAW resonator decreases, as a result, it brings higher requirements on the process and decreased reliability of the device. These disadvantages prevent the SAW resonator from being applied at higher frequencies. The BAW resonator has alleviated various disadvantages of the SAW resonator, moreover, the well-developed semiconductor processes have good compatibility with the manufacturing thereof. However, due to the complicated process and high manufacturing difficulty of the BAW resonator itself, the cost remains high, thereby making it difficult to completely replace the SAW resonator at mid-high frequencies, and even uncompetitive at low frequencies. In addition to the development in the field of communications, the BAW resonator is also widely used in piezoelectric microphones, pressure sensors or other sensor fields due to the excellent performance.

The BAW resonator is different from the SAW resonator in that it uses longitudinal waves to generate resonance in the piezoelectric film, and a propagation direction of the longitudinal waves is a thickness direction of the piezoelectric material. By adjusting the thickness of the piezoelectric material and electrode material, a resonance frequency of the resonator can be easily adjusted. In order to generate resonance, in addition to the piezoelectric material and the electrode layers arranged above and below it to generate electrical excitation, an acoustic reflector that reflects the wave energy is usually provided at an interface. An Air or Bragg reflector is the most commonly used reflector. The Bragg reflector uses a stacked structure of multiple groups of alternating low-acoustic impedance materials and high-acoustic impedance materials to reflect waves. Although such a reflector has high reflectivity, it still cannot avoid energy leakage along the reflector. Compared with the Bragg reflector, air has a better reflection effect on the waves and can block an energy leakage path, thus it can create a resonator with a higher quality factor. In order to introduce air as a reflector in a resonance structure, a cavity structure in or at the substrate is usually formed before depositing the electrode layer and the piezoelectric layer in the related art. Taking the formation of a cavity in a substrate as an example: first, the cavity is filled with a sacrificial material to make the surface smooth; then, an electrode layer and a piezoelectric layer are deposited above the cavity and substrate; and finally, a corrosive liquid or atmosphere that can corrode the sacrificial material is used to contact the sacrificial material through a pre-set discharge channel to discharge the cavity to form an air reflector structure.

During a working process of the BAW resonator, a high-frequency voltage is applied to each of the top electrode and the bottom electrode. Under an action of an alternating electric field, the piezoelectric material deforms. A suspended film layer above the cavity or the acoustic reflector oscillates, generating longitudinal waves parallel to the thickness direction and cluttered waves that propagates along a direction perpendicular to the thickness direction (i.e., a transverse direction). Under a specific-frequency alternating voltage, the suspended film will resonate, and the device will exhibit special electrical characteristics, thereby achieving transmission of a specific-frequency signal.

In the related art, a thin film bulk acoustic resonator (FBAR) device is formed by a thin film piezoelectric material sandwiched between the upper electrode and the lower electrode. The sandwich structure is dangling over a cavity that allows the sound waves to reflect off the electrode/air interface. The tuning frequency of the thin film bulk acoustic resonator is generally fixed, making it difficult to meet the needs of different bandwidths.

### SUMMARY

The embodiments of the present disclosure provide a resonator and a method for forming the resonator, aiming to adjusting the tuning frequency of the resonator by adjusting a thickness of the shunt metal layer and the barrier layer, so as to provide greater flexibility in frequency tuning as well as catering to the future needs of different bandwidths.

In an aspect, an embodiment of the present disclosure provides a resonator, including: a substrate; a bottom electrode provided on the substrate; a piezoelectric layer stacked on the bottom electrode, a surface of the piezoelectric layer facing away from the substrate being provided with a recessed frame; a barrier layer stacked on the piezoelectric layer and covering the recessed frame, the barrier layer and the piezoelectric layer being partially spaced form each other to form an air gap region located at an edge of the recessed frame; at least one shunt metal layer stacked on the barrier layer, along a thickness direction of the resonator, a projection profile of the recessed frame and a projection profile of the air gap region being both located within a projection profile of the at least one shunt metal layer; and a top electrode stacked on the at least one shunt metal layer, an overlapping region of the top electrode, the piezoelectric layer and the bottom electrode along the thickness direction of the resonator being a resonance region, a protruding frame being provided at a surface of the top electrode facing away from the piezoelectric layer, and a projection profile of the protruding frame being located at an edge of the resonance region and at least partially overlapping the resonance region.

As an improvement, the top electrode is a top electrode stacked structure including a top electrode body and a shield layer stacked on a surface of the top electrode body facing away from the piezoelectric layer, and the protruding frame is located at a surface of the shield layer facing away from the top electrode body.

As an improvement, the shield layer includes a dielectric material, and the dielectric material includes at least one of AlN, SiO₂, SiN, SiC or polysilicon.

As an improvement, a material of the barrier layer includes one or a combination of aluminum, molybdenum, platinum, tungsten and ruthenium.

As an improvement, the barrier layer has a thickness ranging from 1 nm to 500 nm.

As an improvement, the resonator further includes a passivation layer that is stacked on a side of the top electrode facing away from the piezoelectric layer and at least partially covers the resonance region.

As an improvement, the protruding frame has a closed ring structure.

As an improvement, the substrate is provided with a cavity formed at a side of the substrate adjacent to the piezoelectric layer along the thickness direction of the resonator, and the bottom electrode covers the cavity.

As an improvement, the bottom electrode, the top electrode, the protruding frame, and the recessed frame are each formed by a conductive metal material, and the conductive metal material includes one or a combination of aluminum, molybdenum, platinum, tungsten and ruthenium.

As an improvement, the at least one shunt metal layer includes two or more shunt metal layers, and two adjacent shunt metal layers of the two or more shunt metal layers are formed by a same material or different materials.

As an improvement, the piezoelectric layer includes a piezoelectric material, and the piezoelectric material is one or a combination of aluminum nitride, zinc oxide, titanium lead zirconate, lithium niobate, and lithium tantalate.

In another aspect, an embodiment of the present disclosure provides a method for forming a resonator, the method including: providing a substrate, forming a cavity in the substrate, and filling the cavity with a sacrificial material; forming a bottom electrode by depositing at a surface of the sacrificial material and the substrate; forming a piezoelectric layer by depositing at a side of the bottom electrode facing away from the substrate, forming an air gap region by patterning a top of the piezoelectric layer, the air gap region being filled with a sacrificial material; forming a recessed frame by depositing at a side of the piezoelectric layer facing away from the bottom electrode, a recessed region being formed between the recessed frame and the air gap region; forming a barrier layer by depositing at a surface of the recessed frame and the air gap region; forming at least one shunt metal layer by depositing at a surface of the barrier layer; forming a top electrode by depositing at a surface of the shunt metal layer, an overlapping region of the top electrode, the piezoelectric layer and the bottom electrode along a thickness direction of the resonator being a resonance region; forming a protruding frame at a surface of the top electrode, a projection profile of the protruding frame being located at an edge of the resonance region and at least partially overlapping with the resonance region; and releasing the sacrificial material to form an air cavity and forming an air gap region between the barrier layer and the piezoelectric layer.

### BRIEF DESCRIPTION OF DRAWINGS

In order to better illustrate technical solutions in embodiments of the present disclosure, the accompanying drawings used in the embodiments are briefly introduced as follows. It should be noted that the drawings described as follows are merely part of the embodiments of the present disclosure, and other drawings can also be acquired by those skilled in the art without paying creative efforts.

FIG. 1 is a schematic diagram of a structure of a resonator according to a first embodiment of the present disclosure;

FIG. 2 is a schematic flow chart of a method for forming a resonator according to a first embodiment of the present disclosure;

FIG. 3A is a schematic diagram of a partial structural of a resonator according to a first embodiment of the present disclosure;

FIG. 3B is a schematic diagram of another partial structural of a resonator according to a first embodiment of the present disclosure;

FIG. 3C is a schematic diagram of another partial structural of a resonator according to a first embodiment of the present disclosure;

FIG. 3D is a schematic diagram of another partial structural of a resonator according to a first embodiment of the present disclosure;

FIG. 3E is a schematic diagram of another structural of a resonator according to a first embodiment of the present disclosure;

FIG. 4 is a schematic diagram of a structure of a resonator according to a second embodiment of the present disclosure; and

FIG. 5 is a schematic diagram of a structure of a resonator according to a third embodiment of the present disclosure.

### DESCRIPTION OF EMBODIMENTS

For better illustrating technical solutions of the present disclosure, embodiments of the present disclosure will be described in detail as follows with reference to the accompanying drawings.

It should be noted that, the described embodiments are merely exemplary embodiments of the present disclosure, which shall not be interpreted as providing limitations to the present disclosure. All other embodiments obtained by those skilled in the art without creative efforts according to the embodiments of the present disclosure are within the scope of the present disclosure.

The terms used in the embodiments of the present disclosure are merely for the purpose of describing particular embodiments but not intended to limit the present disclosure. Unless otherwise noted in the context, the singular form expressions “a”, “an”, “the” and “said” used in the embodiments and appended claims of the present disclosure are also intended to represent plural form expressions thereof.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates that the related objects before and after the character form an “or” relationship.

A film bulk acoustic resonator (FBAR) is generally formed on a semiconductor (such as silicon/silicon carbide/gallium nitride, etc.) substrate that can be used for industrial production, and includes: a sound wave reflective structure, a bottom electrode, a piezoelectric film, a top electrode and a lead out electric connecting wire. A periodic alternating electric field is applied to each of two ends of the piezoelectric film, and the piezoelectric film deforms to generate a sound wave. When the sound wave propagates in a longitudinal direction of the piezoelectric film, it will cause standing wave resonance at a specific frequency. At this time, a thickness of the piezoelectric film is half a wavelength of the sound wave in the piezoelectric film. In this case, the piezoelectric film will exhibit the same electrical resonance characteristics as a quartz crystal resonator and can be used to form an electromagnetic wave resonator and filter. For achieving the overall band-pass performance, the filter consists of resonators connected in series and in parallel, and a frequency of the resonators connected in series is higher than that of the resonators connected in parallel.

In the related art, the recessed frame is processed and formed after the protruding frame is patterned, and processing of the recessed frame will affect the thickness of the protruding frame and also affect the quality factor (Q value) of the resonator.

### First Embodiment

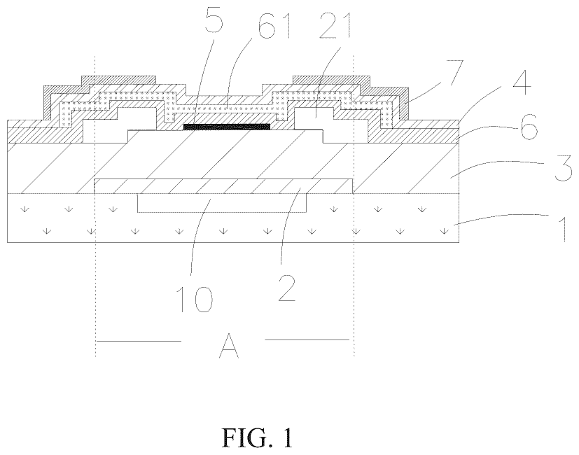

With reference to FIG. 1, which is a schematic cross-sectional structural diagram of a resonator according to a first embodiment of the present disclosure. The resonator 100 includes a substrate 1, a bottom electrode 2, a piezoelectric layer 3 and a top electrode 4 arranged in sequence from bottom to top.

In an example, the bottom electrode 2 is arranged on the substrate 1, the piezoelectric layer 3 is stacked on the bottom electrode 2, the top electrode 4 is formed on the piezoelectric layer 3. An overlapping region of the top electrode 4, the piezoelectric layer 3 and the bottom electrode 2 formed along the thickness direction of the resonator is a resonance region A.

In this embodiment, the substrate 1 is provided with a cavity 10. Along the thickness direction of the resonator, the cavity 10 is formed at a side of the substrate 1, and the bottom electrode 2 covers the cavity 10.

During the forming process, the cavity 10 is filled with a sacrificial material. For example, the sacrificial material may be one or more materials such as silicon dioxide, silicon, and silicon nitride.

In some implementations, the material of the substrate 1 may be any suitable base material well known to those skilled in the art, for example, it may be at least one of the following materials: silicon (Si), germanium (Ge), silicon germanium (SiGe), silicon carbon (SiC), silicon germanium carbon (SiGeC), indium arsenide (InAs), gallium arsenide (GaAs), indium phosphide (InP), or other III/V compound semiconductor; or a multi-layer structure formed by these semiconductors, etc., silicon on insulator (SOI), stacked silicon on insulator (SSOI), stacked silicon germanium on insulator (S—SiGeOI), silicon germanium on insulator (SiGeOI), germanium on insulator (GeOI); or a double side polished wafer (DSP), or a ceramic substrate such as alumina, quartz or a glass substrate.

In some implementations, the material of the bottom electrode 2 includes one or a combination of aluminum, molybdenum, platinum, tungsten, and ruthenium, and can also be formed by other material. In this embodiment, the material of the bottom electrode 2 has good ductility, which facilitates the electrode to have both processability and structural stability, and is beneficial to extending the service life of the electrode.

In some implementations, the piezoelectric layer 3 includes a first surface in electrical contact with the bottom electrode 2 and a second surface in electrical contact with the top electrode 4. In an example, the piezoelectric layer 3 is formed by one or a combination of piezoelectric materials such as aluminum nitride, scandium-doped aluminum nitride, zinc oxide, lead zirconate titanate (PZT), or may be formed by other material. The piezoelectric material can also be doped with some rare earth metals to adjust the piezoelectric property of the piezoelectric layer. The thickness of the piezoelectric layer 3 is within a range from 0.1 μm to 1.5 μm, which is not limited herein.

An air gap region 21 is formed at a top of the piezoelectric layer 3 by patterning, and the air gap region is filled with a sacrificial material. Filling the air gap region with a sacrificial material is beneficial to forming an air bridge and a cantilever structure. In an example, during the forming process, the air gap region is filled with a sacrificial material. In an example, the sacrificial material may be one or a combination of materials such as silicon dioxide, silicon, and silicon nitride.

Further, a surface of the piezoelectric layer 3 facing away from the substrate 1 is provided with a recessed frame 5. Along the thickness direction of the resonator, a projection profile of the recessed frame 5 is located within a projection profile of the bottom electrode 2.

In an example, the material of the recessed frame 5 includes one or a combination of aluminum, molybdenum, platinum, tungsten, and ruthenium, and can also be formed by other material. In this embodiment, the material of the recessed frame 5 has good ductility, which facilitates the recessed frame 5 to have both processability and structural stability, and is beneficial to extending the service life of the recessed frame 5. Since the recessed frame 5 and the protruding frame may have a same material, this may affect the thickness change of the protruding frame, resulting in changes in Q factor performance.

In this embodiment, a barrier layer 6 is provided at a surface of the piezoelectric layer 3 facing away from the substrate 1, and the barrier layer 6 covers the piezoelectric layer 3 and covers the recessed frame 5 located at the surface of the piezoelectric layer 3. The barrier layer 6 is formed by one or a combination of aluminum, molybdenum, platinum, tungsten, and ruthenium, or other material. In this embodiment, the barrier layer 6 can protect the piezoelectric layer 3, ensure the surface quality of the piezoelectric layer 3 to the greatest extent, thereby preventing energy loss and decrease in Q value due to the decrease in surface quality of the piezoelectric layer 3, and also being beneficial to maintaining the piezoelectric property of the piezoelectric material. Moreover, the barrier layer 6 can also physically isolate the recessed frame 5 and the protruding frame, thereby reducing the change in Q factor performance caused by the thickness change of the protruding frame.

In this embodiment, a surface of the barrier layer 6 facing away from the piezoelectric layer 3 is provided with at least one shunt metal layer 61. Along the thickness direction of the resonator, the projection profiles of the recessed frame 5 and the air gap region 21 are both located in ta projection profile of the shunt metal layer 61. It should be noted that the thickness of the shunt metal layer 61 can be adjusted according to the required thickness of the resonator. By stacking at least one shunt metal layer 61, the resonance frequency of the resonator can be adjusted to better meet the resonance requirements of different bandwidths.

In an example, the material of the shunt metal layer 61 includes one or a combination of aluminum, molybdenum, platinum, tungsten, and ruthenium, or other material. The shunt metal layer 61 has a function of frequency tuning, so as to provide greater flexibility in frequency tuning as well as catering to the future needs of different bandwidths. The shunt metal layer can adopt a multi-layer stacked structure. In an example, the shunt metal layer 61 and the bottom electrode 2 may be formed by a same material.

In this embodiment, a top electrode 4 is formed at a surface of the shunt metal layer 61 facing away from the piezoelectric layer 3. The top electrode 4 may be completely located within the resonance region A, and the bottom electrode 2 is partially located within the resonance region A and partially extends outside the resonance region A. it should be noted that according to actual needs, the top electrode 4 can also be partially located outside the resonance region A.

The top electrode 4 has a lead-out structure, which is used to connect an external circuit or signal line, to connect an external electrical signal to the top electrode 4. Similarly, a part of the bottom electrode 2 outside the resonance region forms a lead-out structure of the bottom electrode 2, which is used to connect an external circuit or signal line, to connect an external electrical signal to the bottom electrode 2.

In this embodiment, the resonator further includes a protruding frame 7 located at a surface of the top electrode 4. Along the thickness direction of the resonator, a protruding frame 7 is provided at a surface of the top electrode 4 facing away from the piezoelectric layer 3. A projection profile of the protruding frame 7 is located at an edge of the resonance region A, and at least part of the projection profile of the protruding frame 7 overlaps with the resonance region A. The protruding frame 7 can provide acoustic mismatch to the resonator, thereby improving signal reflection at a boundary of the resonator and reducing the acoustic loss.

In an example, the material of the protruding frame 7 may be the same as the electrode material. The material of the protruding frame 7 may be one or a combination of aluminum, molybdenum, platinum, tungsten, and ruthenium, or other material.

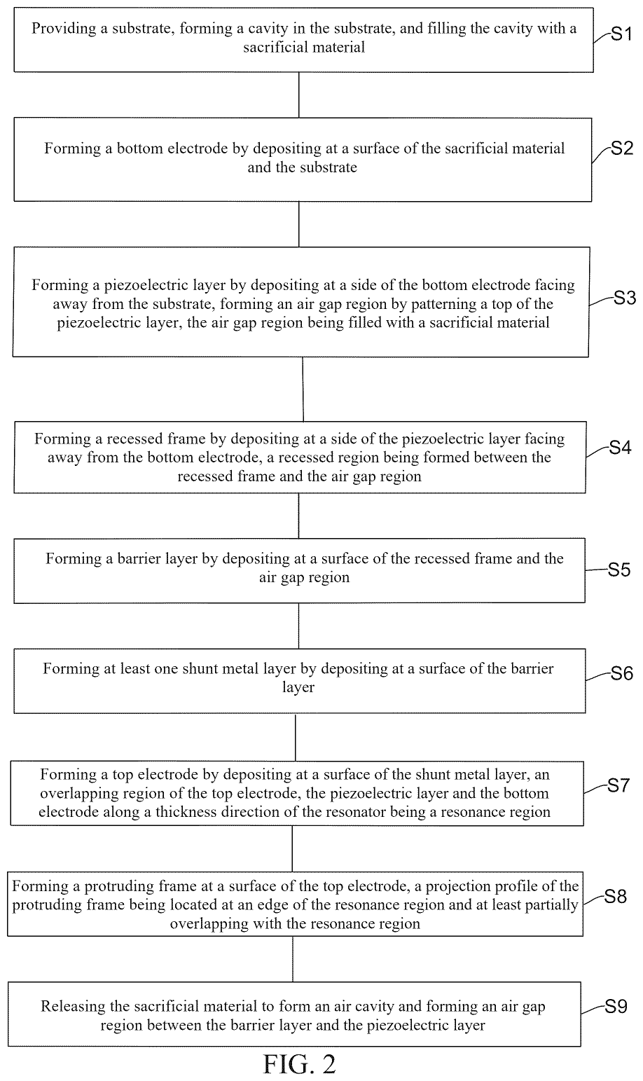

As shown in FIG. 2, a method for forming the resonator includes the following steps.

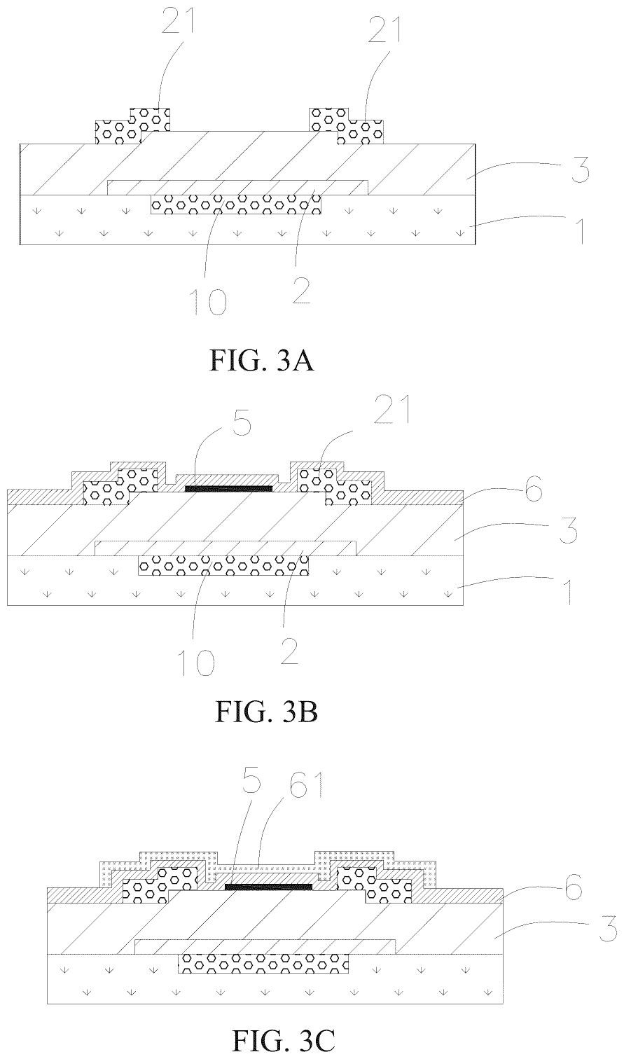

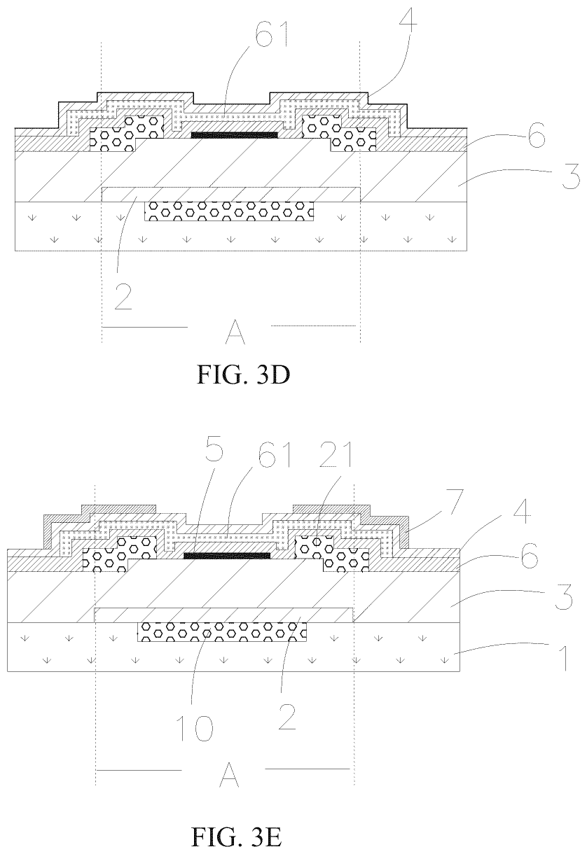

With reference to FIG. 3A, at S1, a substrate 1 is provided, a cavity 10 is formed in the substrate 1, and a sacrificial material is filled in the cavity 10.

In an example, the cavity 10 may be formed in the substrate 1 by an etching process, and a sacrificial material is filled in the cavity 10 in such a manner that the sacrificial material is flush with the substrate 1. The material of the substrate 1 may be any suitable base material well known to those skilled in the art, for example, it may be at least one of the following materials: silicon (Si), germanium (Ge), silicon germanium (SiGe), silicon carbon (SiC), silicon germanium carbon (SiGeC), indium arsenide (InAs), gallium arsenide (GaAs), indium phosphide (InP), or other III/V compound semiconductor; or a multi-layer structure formed by these semiconductors, etc., silicon on insulator (SOI), stacked silicon on insulator (SSOI), stacked silicon germanium on insulator (S—SiGeOI), silicon germanium on insulator (SiGeOI), germanium on insulator (GeOI); or a double side polished wafer (DSP), or a ceramic substrate such as alumina, quartz or a glass substrate.

It can be understood that, in order to introduce air as a reflector in the resonator, before depositing the bottom electrode and the piezoelectric layer, a cavity is first formed in the substrate. Along the thickness direction of the resonator, the cavity 10 is formed at a side of the substrate 1 adjacent to the piezoelectric layer 3. The cavity is filled with a sacrificial material to make the surface flat and smooth. After the resonator is formed, a corrosive liquid that can corrode the sacrificial material is used to contact the sacrificial material via a discharge channel to discharge the cavity to form an air reflector structure.

At S2, a bottom electrode 2 is deposited at a surface of the sacrificial material and the substrate 1.

In this embodiment, the bottom electrode 2 is formed by one or a combination of aluminum, molybdenum, platinum, tungsten, and ruthenium, or other material. The bottom electrode covers the cavity.

At S3, a piezoelectric layer 3 is deposited at a side of the bottom electrode 2 facing away from the substrate 1, and a top of the piezoelectric layer 3 is patterned to form an air gap region 21. The air gap region 21 is filled with a sacrificial material.

In this embodiment, the piezoelectric layer 3 includes a piezoelectric material, which is one of a combination of aluminum nitride, zinc oxide, titanium lead zirconate, lithium niobate, and lithium tantalate.

It can be understood that the air gap region 21 is filled with a sacrificial material, and the air gap region 21 is beneficial to the formation of an air bridge and a cantilever micro-structure. In this embodiment, after the resonator is formed, a corrosive liquid that can corrode the sacrificial material is used to contact the sacrificial material for example via a discharge channel, to discharge the air gap region. The air gap region can reflect sound waves and/or achieve physical isolation.

For example, the sacrificial material may be one or a combination of silicon dioxide, silicon, silicon nitride, etc.

With reference to FIG. 3B, and at S4. a recessed frame 5 is formed by depositing at a side of the piezoelectric layer 3 facing away from the bottom electrode 1, and a recessed region is formed between the recessed frame 5 and the air gap region 21.

For example, the material of the recessed frame 5 is a conductive metal material, which includes or a combination of aluminum, molybdenum, platinum, tungsten, and ruthenium.

With reference to FIG. 3B, at S5, a barrier layer 6 is formed by depositing at a surface of the recessed frame 5 and the air gap region 21.

The barrier layer 6 covers the piezoelectric layer 3 and covers the recessed frame 5 located at a surface of the piezoelectric layer 3. The barrier layer 6 is made of one or a combination of aluminum, molybdenum, platinum, tungsten, and ruthenium, or other material. In this embodiment, the barrier layer 6 can protect the piezoelectric layer 3, ensure the surface quality of the piezoelectric layer to the greatest extent, thereby preventing energy loss and value decrease caused by the decrease in surface quality of the piezoelectric layer 3, and also being beneficial to maintaining the piezoelectric property of the piezoelectric material. Moreover, the barrier layer 6 can also physically isolate the recessed frame 5 and the protruding frame, which can reduce the change in Q factor performance caused by the thickness change of the protruding frame.

With reference to FIG. 3C, at S6, at least one shunt metal layer 61 is formed by depositing at the surface of the barrier layer 6.

In the related art, the protruding frame 7 is usually first formed at a surface of the piezoelectric layer 3, and then the recessed frame 5 is formed by depositing. Since the protruding frame 7 and the recessed frame 5 may be formed by a same material, this may affect the thickness change of the protruding frame 7, thereby causing the quality factor Q value of the resonator to change, which is undesirable.

In an example, the material of the shunt metal layer 61 includes one or a combination of aluminum, molybdenum, platinum, tungsten, and ruthenium, or other material. The shunt metal layer has a function of frequency tuning, so as to provide greater flexibility in frequency tuning as well as catering to the future needs of different bandwidths. The shunt metal layer can adopt a multi-layer stacked structure. In an example, the shunt metal layer 61 and the bottom electrode 2 may be formed by a same material.

With reference to FIG. 3D, at S7, a top electrode 4 is formed by depositing at a surface of the shunt metal layer 61. An overlapping region of the top electrode 4, the piezoelectric layer 3 and the bottom electrode 2 is the resonance region A.

The material of the top electrode 4 and the material of the bottom electrode 2 may be a conductive metal material, which includes one or a combination of aluminum, molybdenum, platinum, tungsten, and ruthenium.

With reference to FIG. 3E, an S8, a protruding frame 7 is formed at a surface of the top electrode 4. A projection profile of the protruding frame 7 is located at an edge of the resonance region A and at least partially overlaps with the resonance region A.

The material of the protruding frame is a conductive metal material, which includes one or a combination of aluminum, molybdenum, platinum, tungsten, and ruthenium.

At S9, the sacrificial material is released to form an air cavity, and an air gap region is formed between the barrier layer and the piezoelectric layer.

In this way, the resonator shown in FIG. 1 is formed.

According to the method for forming the resonator provided in the present disclosure, the recessed frame 5 is formed by depositing at the surface of the piezoelectric layer 2, the barrier layer 6 covers the recessed frame 5, and then at least one shunt metal layer 61 is formed at the surface of the barrier layer 6. The tuning frequency of the resonator can be adjusted by adjusting a thickness of the shunt metal layer 61 and the barrier layer 6, so as to provide greater flexibility in frequency tuning as well as catering to the future needs of different bandwidths. Then the protruding frame 7 is formed at the surface of the top electrode 4, and the protruding frame 7 and the recessed frame 5 are separately formed in the forming process. The processing of the recessed frame 5 will not affect the thickness of the protruding frame 7, so that the thickness of the protruding frame 7 can be better controlled, thereby controlling the quality factor (Q value) of the resonator.

### Second Embodiment

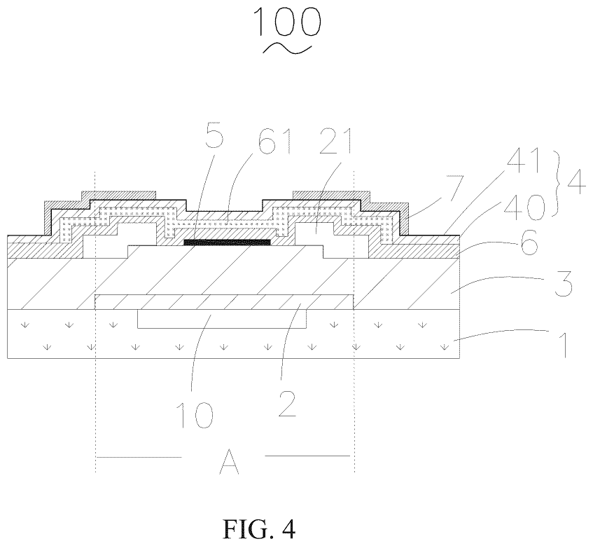

The present disclosure further provides another embodiment, as shown ion FIG. 4, which is a schematic diagram of a structure of a resonator according to a second embodiment of the present disclosure. With reference to FIG. 4, a structure of the resonator 100 is basically the same as the structure of the resonator described in the first embodiment, except for the following differences.

The top electrode 4 has a top electrode stacked structure. The top electrode stacked structure includes a top electrode body 40 and a shield layer 41 stacked at a surface of the top electrode body 40 facing away from the piezoelectric layer 3. The protruding frame 7 is formed at a surface of the shield layer 41 facing away from the top electrode body 40.

In an example, the shield layer 41 covers the top electrode body 40, and the shield layer 41 includes a dielectric material. The dielectric material includes at least one of AlN, SiO₂, SiN, SiC and polysilicon, or other material. In this embodiment, the shield layer 41 can protect the top electrode body 40, and can also help extend the service life of the top electrode 4, and can also protect subsequent processing steps from affecting the layer structure below the top electrode.

In this embodiment, the protruding frame 7 is formed at a surface of the shield layer 41 facing away from the top electrode body 40. The protruding frame 7 is formed around the resonance region A of the resonator, thereby providing acoustic mismatch to the resonator, and thus improving the signal reflection at the boundary of the resonator and reducing the acoustic loss.

### Third Embodiment

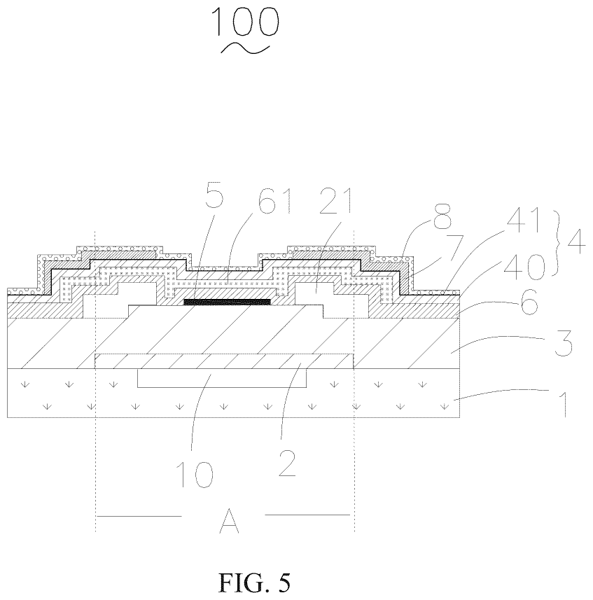

The present disclosure further provides another embodiment, as shown ion FIG. 5, which is a schematic diagram of a structure of a resonator according to a third embodiment of the present disclosure. With reference to FIG. 5, a structure of the resonator 100 is basically the same as the structure of the resonator described in the second embodiment, except for the following differences.

The piezoelectric resonator 100 further includes a passion layer 8, which is stacked at a side of the top electrode 4 facing away from the piezoelectric layer 3 and at least partially covers the resonance region A. Of course, the lead-out structure of the top electrode needs to be connected to the top electrode body 40 by passing through the passion layer 8.

The passivation layer 8 can effectively protect the top electrode 4 and the piezoelectric layer 3, protect the resonator from corrosion or any pollution source, and improve the structural reliability. In an example, the passion layer 8 may be formed by a material such as AlN, SiO₂, SiN, SiC or polysilicon.

In order to further protect the piezoelectric resonator, an oxide layer 9 can be provided at a surface of the passion layer 8, and the oxide layer 9 can be used as a hard mask during subsequent patterning of the lead-out structure of the top electrode. It should be noted that after the electrode lead-out structure is installed, the oxide layer 9 needs to be etched or stripped away.

Except for the differences described above, the structure is the same as the structure described in the first embodiment or the second embodiment, and the technical problems solved and the technical effects achieved are also the same, which will not be described again herein.

The above-described embodiments are merely preferred embodiments of the present disclosure and are not intended to limit the present disclosure. Any modifications, equivalent substitutions and improvements made within the principle of the present disclosure shall fall into the protection scope of the present disclosure.

What is claimed is:

1. A resonator, comprising:
a substrate;
a bottom electrode provided on the substrate;
a piezoelectric layer stacked on the bottom electrode, a surface of the piezoelectric layer facing away from the substrate being provided with a recessed frame;
a barrier layer stacked on the piezoelectric layer and covering the recessed frame, wherein the barrier layer and the piezoelectric layer are partially spaced form each other to form an air gap region located at an edge of the recessed frame;
at least one shunt metal layer stacked on the barrier layer, wherein along a thickness direction of the resonator, a projection profile of the recessed frame and a projection profile of the air gap region are both located within a projection profile of the at least one shunt metal layer; and
a top electrode stacked on the at least one shunt metal layer, wherein an overlapping region of the top electrode, the piezoelectric layer and the bottom electrode along the thickness direction of the resonator is a resonance region, a protruding frame is provided at a surface of the top electrode facing away from the piezoelectric layer, and a projection profile of the protruding frame is located at an edge of the resonance region and at least partially overlaps the resonance region.

2. The resonator as described in claim 1, wherein the top electrode is a top electrode stacked structure comprising a top electrode body and a shield layer stacked on a surface of the top electrode body facing away from the piezoelectric layer, and the protruding frame is located at a surface of the shield layer facing away from the top electrode body.

3. The resonator as described in claim 2, wherein the shield layer comprises a dielectric material, and the dielectric material comprises at least one of AlN, SiO₂, SiN, SiC or polysilicon.

4. The resonator as described in claim 1, wherein a material of the barrier layer comprises one or a combination of aluminum, molybdenum, platinum, tungsten and ruthenium.

5. The resonator as described in claim 1, wherein the barrier layer has a thickness ranging from 1 nm to 500 nm.

6. The resonator as described in claim 1, wherein the resonator further comprises a passivation layer that is stacked on a side of the top electrode facing away from the piezoelectric layer and at least partially covers the resonance region.

7. The resonator as described in claim 1, wherein the protruding frame has a closed ring structure.

8. The resonator as described in claim 1, wherein the substrate is provided with a cavity formed at a side of the substrate adjacent to the piezoelectric layer along the thickness direction of the resonator, and the bottom electrode covers the cavity.

9. The resonator as described claim 1, wherein the bottom electrode, the top electrode, the protruding frame, and the recessed frame are each formed by a conductive metal material, and the conductive metal material comprises one or a combination of aluminum, molybdenum, platinum, tungsten and ruthenium.

10. The resonator as described claim 1, wherein the at least one shunt metal layer comprises two or more shunt metal layers, and two adjacent shunt metal layers of the two or more shunt metal layers are formed by a same material or different materials.

11. The resonator as described claim 1, wherein the piezoelectric layer comprises a piezoelectric material, and the piezoelectric material is one or a combination of aluminum nitride, zinc oxide, titanium lead zirconate, lithium niobate, and lithium tantalate.

12. A method for forming the resonator as described in claim 1, the method comprising:
providing a substrate, forming a cavity in the substrate, and filling the cavity with a sacrificial material;
forming a bottom electrode by depositing at a surface of the sacrificial material and the substrate;
forming a piezoelectric layer by depositing at a side of the bottom electrode facing away from the substrate, forming an air gap region by patterning a top of the piezoelectric layer, the air gap region being filled with a sacrificial material;
forming a recessed frame by depositing at a side of the piezoelectric layer facing away from the bottom electrode, a recessed region being formed between the recessed frame and the air gap region;
forming a barrier layer by depositing at a surface of the recessed frame and the air gap region;
forming at least one shunt metal layer by depositing at a surface of the barrier layer;
forming a top electrode by depositing at a surface of the shunt metal layer, an overlapping region of the top electrode, the piezoelectric layer and the bottom electrode along a thickness direction of the resonator being a resonance region;
forming a protruding frame at a surface of the top electrode, a projection profile of the protruding frame being located at an edge of the resonance region and at least partially overlapping with the resonance region; and
releasing the sacrificial material to form an air cavity and forming an air gap region between the barrier layer and the piezoelectric layer.
